(19) United States
(12) Patent Application Publication
(10) Pub. No.: US 2026/0354001 A1
(43) Pub. Date: Nov. 5, 2026

(54) DISPLAY DEVICE AND METHOD OF MANUFACTURING THE SAME

(71) Applicant: YouB LAB Inc., Seongnam-si (KR)

(72) Inventors: Bong Hyun YOU, Seoul (KR); Je In YOU, Seongnam-si, Gyeonggi-do (KR)

(21) Appl. No.: 19/720,858

(22) Filed: Jun. 25, 2026

Related U.S. Application Data
(63) Continuation of application No. PCT/KR2024/018169, filed on Nov. 18, 2024.

(30) Foreign Application Priority Data
Aug. 14, 2024 (KR) 10-2024-0109448

(51) Int. Cl. H10K 59/80; H10K 59/12; H10K 59/95

(52) U.S. Cl. CPC H10K 59/8794; H10K 59/1201; H10K 59/95

(57) ABSTRACT

A display device includes a display panel including at least one pixel, a printed circuit board electrically connected to the pixel, a heat dissipation layer including graphite and disposed between the display panel and the printed circuit board, a cover layer disposed on one surface of the heat dissipation layer, and a side cover member including resin and covering a side surface of the heat dissipation layer.

### CROSS-REFERENCE TO RELATED APPLICATION

This application is a bypass continuation application of International Patent Application No. PCT/KR2024/018169, filed on Nov. 18, 2024, which is based on and claims the benefit of priority to Korean Patent Application No. 10-2024-0109448, filed Aug. 14, 2024, the disclosures of which are hereby incorporated by reference in their entireties.

### TECHNICAL FIELD

The present invention relates to a display device and a method of manufacturing the same. More particularly, the present invention relates to a display device including a multi-functional member that performs heat dissipation, electromagnetic interference (EMI) shielding, and electrostatic discharge (ESD) shielding.

### BACKGROUND

In general, a display device includes a display panel and a display panel driver. The display panel displays an image based on an input image and includes a plurality of gate lines, a plurality of data lines, and a plurality of pixels. The display panel driver includes a gate driver that provides gate signals to the plurality of gate lines, a data driver that provides data voltages to the plurality of data lines, and a driving controller that controls operations of the gate driver and the data driver.

The display device may generate heat during operation. When the display device does not properly dissipate heat, the display device may be overheated and damaged. In general, in the case of an OLED self-emission display, a current for light emission is transferred to an organic EL diode so that heat is generated. Such heat may cause degradation such as Burn In of the EL material, thereby deteriorating image quality. In addition, when such heat generation contacts a human body at the front of the display, it may cause human injury such as burns.

In addition, the display device may generate electromagnetic waves during operation. When the electromagnetic waves are not properly shielded and a user is exposed to the electromagnetic waves for a long time, there is a concern that health problems of the user may be caused. In addition, the display device may generate static electricity during operation. When the static electricity is not properly shielded, the display device may malfunction or be damaged.

### SUMMARY

One object of the present invention is to provide a display device including a multi-functional member having improved thermal conductivity.

Another object of the present invention is to provide a method of manufacturing the display device.

However, the objects of the present invention are not limited to the objects described above, and may be variously expanded without departing from the spirit and scope of the present invention.

To achieve the one object of the present invention described above, a display device according to an embodiment of the present invention includes a display panel, a printed circuit board, a heat dissipation layer, a cover layer, and a side cover member. The display panel includes at least one pixel. The printed circuit board is disposed under the display panel and is electrically connected to the pixel. The heat dissipation layer includes graphite and is disposed between the display panel and the printed circuit board. The cover layer is disposed on one surface of the heat dissipation layer facing the printed circuit board. The side cover member covers a side surface of the heat dissipation layer.

In an embodiment, the cover layer may include a material identical to a material of the side cover member.

In an embodiment, the cover layer may include a material different from a material of the side cover member.

In an embodiment, the cover layer may include at least one material selected from a resin group consisting of acryl, epoxy, polyurethane, and silicone.

In an embodiment, the cover layer may further include at least one material selected from a filler group consisting of boron nitride (BN), graphite powder, graphene, carbon fiber, and carbon nano tube. A mass ratio of the resin group included in the cover layer may be about 30 wt % to about 90 wt %. A mass ratio of the filler group included in the cover layer may be about 10 wt % to about 70 wt %.

In an embodiment, an average thickness of the heat dissipation layer may be greater than an average thickness of the cover layer. The average thickness of the heat dissipation layer may be about 10 μm to about 1000 μm. The average thickness of the cover layer may be about 5μm to about 50 μm.

In an embodiment, a thermal conductivity of the heat dissipation layer may be about 100 W/(m·K) to about 1700 W/(m·K).

In an embodiment, the cover layer may be adhered to the one surface of the heat dissipation layer and may include polyethylene terephthalate (PET).

In an embodiment, a contact hole penetrating the cover layer in a thickness direction may be defined in the cover layer. The heat dissipation layer may be connected to the printed circuit board through the contact hole.

In an embodiment, the display device may further include an adhesive layer disposed between the display panel and the heat dissipation layer. An average thickness of the adhesive layer may be greater than an average thickness of the cover layer and smaller than an average thickness of the heat dissipation layer. The adhesive layer may couple the heat dissipation layer and the display panel to each other and may include polyethylene terephthalate.

To achieve the one object of the present invention described above, a display device according to an embodiment of the present invention includes a display panel, a printed circuit board, a heat dissipation layer, a first cover layer, and a second cover layer. The display panel includes at least one pixel. The printed circuit board is disposed under the display panel and is electrically connected to the pixel. The heat dissipation layer includes graphite and is disposed between the display panel and the printed circuit board. The first cover layer is disposed on one surface of the heat dissipation layer facing the printed circuit board, and extends from the one surface to cover a part of a side surface of the heat dissipation layer. The second cover layer is disposed on the other surface of the heat dissipation layer opposite to the one surface, and extends from the other surface to contact the first cover layer.

In an embodiment, the first cover layer may be adhered to the one surface of the heat dissipation layer and may include polyethylene terephthalate. The second cover layer may couple the heat dissipation layer and the display panel to each other on the other surface of the heat dissipation layer and may include polyethylene terephthalate.

In an embodiment, a contact hole penetrating the first cover layer in a thickness direction may be defined in the first cover layer. The heat dissipation layer may be connected to the printed circuit board through the contact hole.

In an embodiment, the first cover layer and the second cover layer may be integrally formed to define a single metal coating layer surrounding all of the one surface, the other surface, and the side surface of the heat dissipation layer. An average thickness of the metal coating layer may be about 1 μm to about 20 μm.

To achieve another object of the present invention described above, a method of manufacturing a display device according to an embodiment of the present invention includes forming a cover layer on one surface of a heat dissipation layer including graphite, forming an adhesive layer on the other surface of the heat dissipation layer opposite to the one surface, and covering a side surface of the heat dissipation layer using a polymer material or a metal material.

In an embodiment, the forming of the cover layer on the one surface of the heat dissipation layer may include unrolling a graphite sheet in a roll state, coating a material forming the cover layer on one surface of the graphite sheet, and cutting the graphite sheet and the coated cover layer. In the covering of the side surface of the heat dissipation layer, the side surface of the heat dissipation layer may be surrounded by a side cover member.

In an embodiment, the forming of the cover layer on the one surface of the heat dissipation layer may include unrolling a graphite sheet in a roll state, forming the heat dissipation layer by cutting the graphite sheet, and coating a material forming the cover layer on the one surface of the heat dissipation layer. In the covering of the side surface of the heat dissipation layer, the side surface of the heat dissipation layer may be surrounded by a side cover member.

In an embodiment, the covering of the side surface of the heat dissipation layer may include stretching the cover layer from the one surface of the heat dissipation layer to the side surface, forming the adhesive layer from the other surface of the heat dissipation layer to the side surface, and bringing the cover layer and the adhesive layer into contact with each other so that the cover layer and the adhesive layer seal the side surface of the heat dissipation layer.

In an embodiment, the forming of the cover layer on the one surface of the heat dissipation layer may include unrolling a graphite sheet in a roll state, forming the heat dissipation layer by cutting the graphite sheet, and plating the heat dissipation layer so that the cover layer surrounds all of the one surface, the other surface, and the side surface of the heat dissipation layer. In the forming of the adhesive layer on the other surface of the heat dissipation layer opposite to the one surface, the adhesive layer may contact the cover layer surrounding the heat dissipation layer.

In an embodiment, the method of manufacturing the display device may further include forming a contact hole penetrating the cover layer in a thickness direction, and electrically connecting the cover layer and a printed circuit board through the contact hole. The cover layer may include at least one material selected from a resin group consisting of acryl, epoxy, polyurethane, polyethylene terephthalate, and silicone.

The display device according to embodiments of the present invention may include a cover layer for covering a heat dissipation layer including graphite. Accordingly, it is possible to prevent a phenomenon in which impurities such as particles flow into the display panel or the printed circuit board from a surface of the heat dissipation layer. In addition, since the display device includes a multi-functional member including the heat dissipation layer and the cover layer, the display device may easily perform roles of electromagnetic interference shielding and electrostatic discharge shielding.

In the method of manufacturing the display device according to embodiments of the present invention, since the cover layer covering the heat dissipation layer is formed by being coated, attached, or plated on the heat dissipation layer, a lamination process accompanied by heat for protecting the heat dissipation layer is not separately required, and accordingly, defects occurring in the display device may be reduced. Therefore, reliability of the display device may be improved.

However, the effects of the present invention are not limited to the effects described above, and may be variously expanded without departing from the spirit and scope of the present invention.

### BRIEF DESCRIPTION OF THE DRAWINGS

Embodiments will be more clearly understood from the following detailed description taken in conjunction with the accompanying drawings in which:

FIG. 1 is a plan view illustrating a display device according to an embodiment of the present invention.

FIG. 2 is a cross-sectional view illustrating an unfolded state of a cross section of the display device of FIG. 1 taken along line I-I′.

FIG. 3 is a cross-sectional view illustrating a bent state of a cross section of the display device of FIG. 1 taken along line I-I′.

FIG. 4 is a cross-sectional view illustrating a cross section of a part of the display panel of FIG. 1.

FIG. 5 is a cross-sectional view illustrating a cross section of the multi-functional member included in the display device of FIG. 1 taken along line II-II′.

FIGS. 6 to 11 are views for explaining an example of a method of manufacturing the display device of FIG. 1.

FIGS. 12 and 13 are views for explaining another example of a method of manufacturing the display device of FIG. 1.

FIG. 14 is a cross-sectional view illustrating a cross section of a display device according to another embodiment of the present invention.

FIG. 15 is a cross-sectional view illustrating a cross section of a multi-functional member and a circuit board included in the display device of FIG. 14.

FIGS. 16 to 18 are views for explaining a method of manufacturing the display device of FIG. 14.

FIG. 19 is a cross-sectional view illustrating a cross section of a display device according to yet another embodiment of the present invention.

FIG. 20 is a cross-sectional view illustrating a cross section of a multi-functional member included in the display device of FIG. 19.

FIG. 21 is a view for explaining a method of manufacturing the display device of FIG. 19.

FIG. 22 is a cross-sectional view illustrating a cross section of a display device according to yet another embodiment of the present invention.

FIG. 23 is a cross-sectional view illustrating a cross section of a multi-functional member and a circuit board included in the display device of FIG. 22.

FIG. 24 is a view for explaining a method of manufacturing the display device of FIG. 22.

FIG. 25 is a cross-sectional view illustrating a cross section of a display device according to yet another embodiment of the present invention.

FIG. 26 is a cross-sectional view illustrating a cross section of a multi-functional member included in the display device of FIG. 25.

### DETAILED DESCRIPTION

With respect to the embodiments of the present invention disclosed in the specification, specific structural and functional descriptions are exemplified only for the purpose of describing the embodiments of the present invention, and the embodiments of the present invention may be implemented in various forms and should not be construed as being limited to the embodiments described in the specification.

Since the present invention may apply various changes and have various forms, specific embodiments will be illustrated in the drawings and described in detail in the specification. However, this is not intended to limit the present invention to a specific disclosed form, and it should be understood that the present invention includes all changes, equivalents, and substitutes included in the spirit and technical scope of the present invention.

Terms such as first and second may be used to describe various components, but the components should not be limited by the terms. The terms may be used for the purpose of distinguishing one component from another component. For example, without departing from the scope of the present invention, a first component may be referred to as a second component, and similarly, a second component may also be referred to as a first component.

When a component is referred to as being “connected” or “coupled” to another component, it may be directly connected or coupled to the other component, but it should be understood that other components may exist in between. On the other hand, when a component is referred to as being “directly connected” or “directly coupled” to another component, it should be understood that there are no other components in between. Other expressions describing the relationship between components, that is, “between” and “directly between” or “neighboring” and “directly neighboring”, should be interpreted in the same manner.

The terms used in the present application are only used to describe specific embodiments, and are not intended to limit the present invention. Singular expressions include plural expressions unless the context clearly indicates otherwise. In the present application, terms such as “include” or “have” are intended to designate the presence of features, numbers, steps, operations, components, parts, or combinations thereof described in the specification, but should be understood not to preclude the presence or addition of one or more other features, numbers, steps, operations, components, parts, or combinations thereof.

Unless defined otherwise, all terms used herein, including technical or scientific terms, have the same meaning as commonly understood by those of ordinary skill in the art to which the present invention belongs. Terms such as those defined in commonly used dictionaries should be interpreted as having a meaning consistent with the meaning in the context of the related art, and unless explicitly defined in the present application, are not interpreted in an ideal or excessively formal meaning.

Meanwhile, when an embodiment is otherwise implementable, a function or operation specified in a specific block may occur in a different order from the order specified in a flowchart. For example, two consecutive blocks may actually be performed substantially simultaneously, and the blocks may be performed in reverse order depending on a related function or operation.

Hereinafter, preferred embodiments of the present invention will be described in more detail with reference to the accompanying drawings. The same reference numerals are used for the same components in the drawings, and redundant descriptions of the same components are omitted.

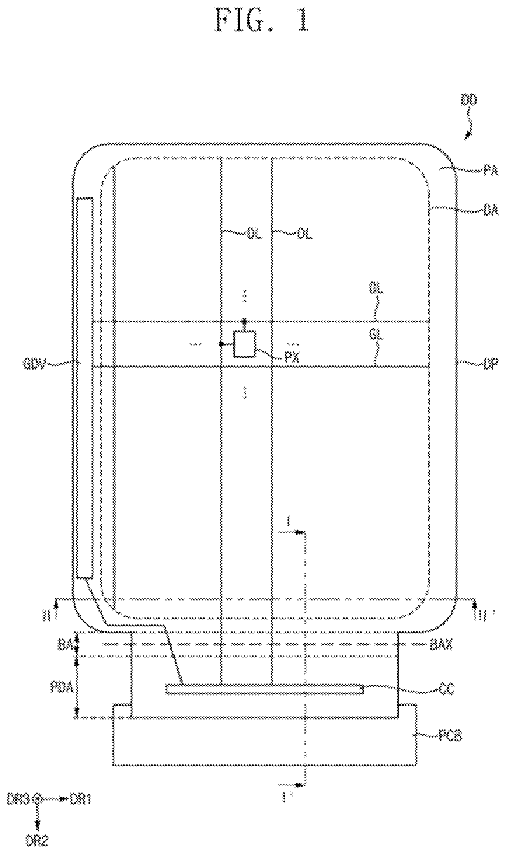

FIG. 1 is a plan view illustrating a display device according to an embodiment of the present invention.

Referring to FIG. 1, the display device (DD) according to an embodiment of the present invention may be a device that is activated according to an electrical signal. For example, the display device (DD) may be a small-sized display device used in small electronic devices such as a smartphone, a mobile phone, a smart watch, a game machine, and a camera. In addition, the display device (DD) may be a medium-or-large-sized display device used in medium-or-large electronic devices such as a notebook computer, a tablet PC, a television, a computer monitor, a vehicle monitor, and an external billboard.

In the present specification, one plane may be defined by a first direction (DR1) and a second direction (DR2) intersecting the first direction (DR1). For example, the second direction (DR2) may perpendicularly intersect the first direction (DR1). In addition, a third direction (DR3) may perpendicularly intersect the plane.

The display device (DD) may include a display panel (DP), a pixel (PX), a plurality of gate lines (GL), a plurality of data lines (DL), a gate driver (GDV), a driving circuit part (CC), and a printed circuit board (PCB).

The display panel (DP) may include a display area (DA), a peripheral area (PA), a bending area (BA), and a pad area (PDA). As the display device (DD) includes the display panel (DP), the display device (DD) may also include the display area (DA), the peripheral area (PA), the bending area (BA), and the pad area (PDA).

The display area (DA) may be an area that generates light or displays an image by adjusting transmittance of light provided from an external light source. At least one pixel (PX) may be disposed in the display area (DA). For example, the display panel (DP) may include at least one pixel (PX).

The pixel (PX) may emit light to generate an image. For example, a plurality of pixels (PX) may be arranged in the first direction (DR1) and the second direction (DR2). In addition, the pixel (PX) may include a plurality of sub-pixels that emit light of different colors from each other. For example, the sub-pixels may include a red sub-pixel that emits red light, a green sub-pixel that emits green light, and a blue sub-pixel that emits blue light.

A plurality of gate lines (GL) and a plurality of data lines (DL) may be disposed in the display area (DA). The gate lines (GL) and the data lines (DL) may intersect each other. The gate lines (GL) may extend in the first direction (DR1). Each of the gate lines (GL) may be spaced apart from each other in the second direction (DR2). The data lines (DL) may extend along the second direction (DR2). Each of the data lines (DL) may be spaced apart from each other in the first direction (DR1). In the display area (DA), the pixel (PX) may be disposed in an area where one of the gate lines (GL) and one of the data lines (DL) intersect. The pixel (PX) may be electrically connected to the gate line and the data line.

The peripheral area (PA) may be adjacent to the display area (DA). For example, the peripheral area (PA) may surround at least a part of the display area (DA). The peripheral area (PA) may be an area that does not display an image. However, the peripheral area (PA) according to embodiments of the present invention is not necessarily limited thereto, and an image may be displayed in at least a part of the peripheral area (PA). For example, a pixel (PX) that emits light may be disposed in at least a part of the peripheral area (PA).

A gate driver (GDV) for driving the pixel (PX) may be disposed in the peripheral area (PA). The gate driver (GDV) may transfer gate signals such as an emission control signal and a scan signal to the pixel (PX) through the gate lines (GL). The pixel (PX) may emit light based on the gate signals.

The bending area (BA) may be adjacent to the peripheral area (PA). For example, the bending area (BA) may be adjacent to one side of the peripheral area (PA) in the second direction (DR2). The bending area (BA) may be bent along a bending axis (BAX). For example, the bending axis (BAX) may extend along the first direction (DR1). The bending axis (BAX) may be a central axis that bends the display panel (DP) in the bending area (BA). However, although FIG. 1 illustrates that the display panel (DP) is bent in the bending area (BA), the display panel (DP) according to embodiments of the present invention is not necessarily limited thereto, and a flexible circuit film connected to one end of the display panel (DP) in the bending area (BA) may be bent along the bending axis (BAX), and the other end of the flexible circuit film opposite to the one end may be electrically connected to the printed circuit board (PCB).

The pad area (PDA) may be adjacent to the bending area (BA). For example, the pad area (PDA) may be adjacent to one side of the bending area (BA) in the second direction (DR2). The driving circuit part (CC) may be disposed on the display panel (DP). In an embodiment, the driving circuit part (CC) may include a data driver. For example, the driving circuit part (CC) may provide a data signal for driving the pixel (PX). The pixel (PX) may emit light based on the data signal.

The printed circuit board (PCB) may be adjacent to the display panel (DP) located in the pad area (PDA). At least a part of the printed circuit board (PCB) may overlap at least a part of the display panel (DP) located in the pad area (PDA). In an embodiment, the printed circuit board (PCB) may include a power voltage generator. For example, the printed circuit board (PCB) may generate a power voltage to be supplied to the pixel (PX).

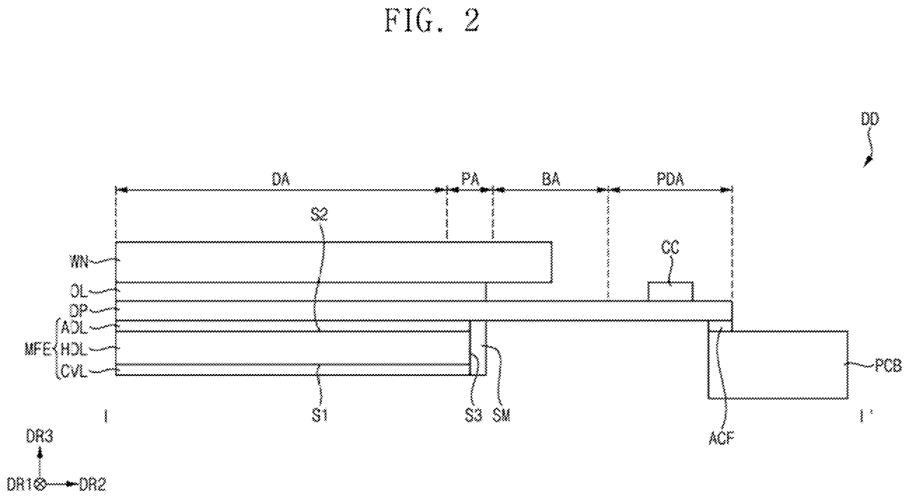

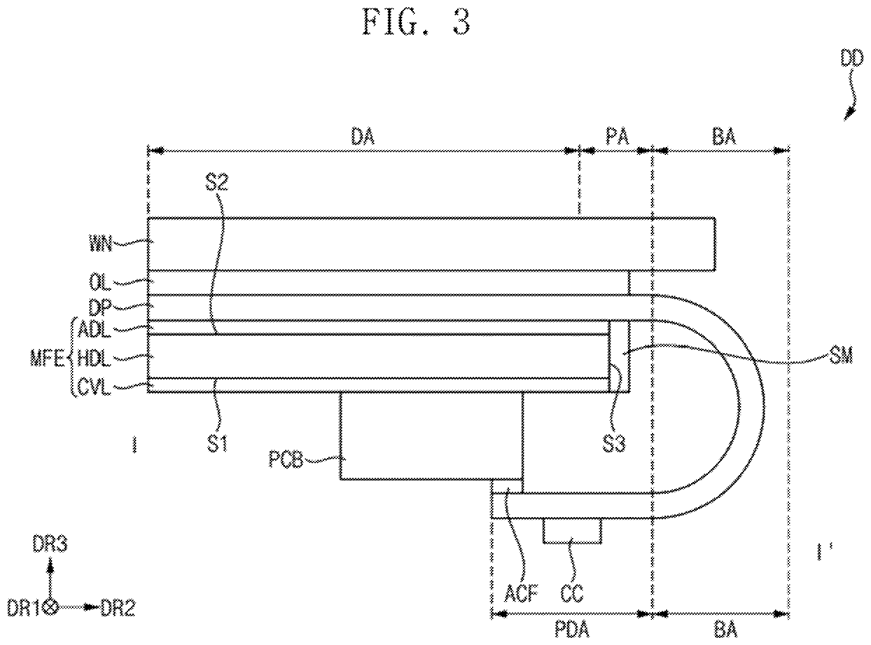

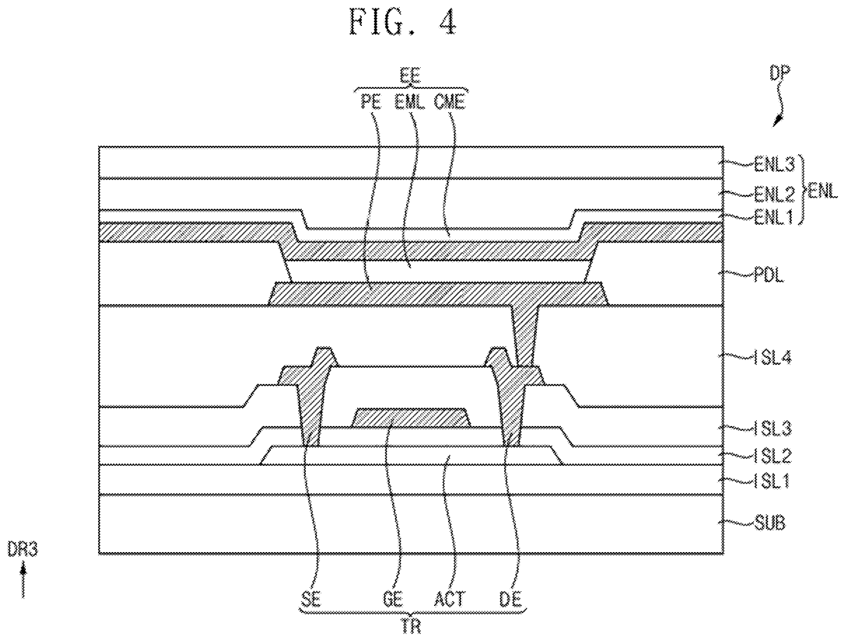

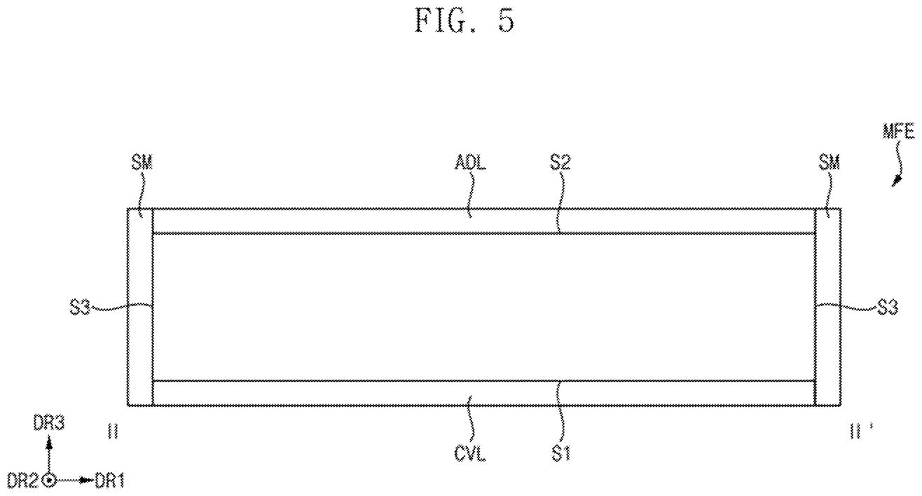

FIG. 2 is a cross-sectional view illustrating an unfolded state of a cross section of the display device of FIG. 1 taken along line I-I′. FIG. 3 is a cross-sectional view illustrating a bent state of a cross section of the display device of FIG. 1 taken along line I-I′. FIG. 4 is a cross-sectional view illustrating a cross section of a part of the display panel of FIG. 1. FIG. 5 is a cross-sectional view illustrating a cross section of the multi-functional member included in the display device of FIG. 1 taken along line II-II′.

Referring to FIGS. 2 to 5, the display device (DD) may include the display panel (DP), the driving circuit part (CC), a multi-functional member (MFE), a side cover member (SM), the printed circuit board (PCB), an anisotropic conductive film (ACF), an optical functional layer (OL), and a window layer (WN). The multi-functional member (MFE) may include a heat dissipation layer (HDL), a cover layer (CVL), and an adhesive layer (ADL).

The display panel (DP) may include a substrate (SUB), a first insulating layer (ISL1), an active layer (ACT), a second insulating layer (ISL2), a gate electrode (GE), a third insulating layer (ISL3), a source electrode (SE), a drain electrode (DE), a fourth insulating layer (ISL4), a pixel electrode (PE), a light emitting layer (EML), a common electrode (CME), and an encapsulation layer (ENL). The encapsulation layer (ENL) may include a first encapsulation layer (ENL1), a second encapsulation layer (ENL2), and a third encapsulation layer (ENL3).

The substrate (SUB) may form a base of the display panel (DP). In an embodiment, the substrate (SUB) may be a transparent insulating substrate. For example, the substrate (SUB) may include glass, quartz, plastic, or the like. These may be used alone or in combination with each other.

The first insulating layer (ISL1) may be disposed on the substrate (SUB). The first insulating layer (ISL1) may prevent impurities from diffusing from the substrate (SUB) to the active layer (ACT). The first insulating layer (ISL1) may include an inorganic insulating material such as silicon, silicon nitride, or silicon oxide. The active layer (ACT) may be disposed on the first insulating layer (ISL1).

The active layer (ACT) may include amorphous silicon, polycrystalline silicon, or an oxide semiconductor. The active layer (ACT) may include a source area and a drain area doped with impurities, and a channel area disposed between the source area and the drain area.

The second insulating layer (ISL2) may be disposed on the first insulating layer (ISL1). The second insulating layer (ISL2) may cover the active layer (ACT) on the first insulating layer (ISL1). In an embodiment, the second insulating layer (ISL2) may have a substantially uniform thickness along a profile of the active layer (ACT). However, the second insulating layer (ISL2) according to embodiments of the present invention is not necessarily limited thereto, and the second insulating layer (ISL2) may sufficiently cover the active layer (ACT) and have a substantially flat top surface without generating a step around the active layer (ACT). The second insulating layer (ISL2) may include an inorganic insulating material.

The gate electrode (GE) may be disposed on the second insulating layer (ISL2). The gate electrode (GE) may overlap the channel area of the active layer (ACT) on a plane. The gate electrode (GE) may include a metal, an alloy, a conductive metal oxide, a conductive metal nitride, a transparent conductive material, or the like.

The third insulating layer (ISL3) may be disposed on the second insulating layer (ISL2). The third insulating layer (ISL3) may cover the gate electrode (GE) on the second insulating layer (ISL2). In an embodiment, the third insulating layer (ISL3) may have a substantially uniform thickness along a profile of the gate electrode (GE). However, the third insulating layer (ISL3) according to embodiments of the present invention is not necessarily limited thereto, and the third insulating layer (ISL3) may sufficiently cover the gate electrode (GE) and have a substantially flat top surface without generating a step around the gate electrode (GE).

The source electrode (SE) and the drain electrode (DE) may be disposed on the third insulating layer (ISL3). The source electrode (SE) and the drain electrode (DE) may contact the active layer (ACT) through contact holes penetrating the second insulating layer (ISL2) and the third insulating layer (ISL3). The source electrode (SE) and the drain electrode (DE) may overlap the source area and the drain area of the active layer (ACT), respectively. Each of the source electrode (SE) and the drain electrode (DE) may include a metal, an alloy, a conductive metal oxide, a conductive metal nitride, a transparent conductive material, or the like. The active layer (ACT), the gate electrode (GE), the source electrode (SE), and the drain electrode (DE) may define a transistor (TR) for operating a pixel (for example, the pixel (PX) of FIG. 1).

The fourth insulating layer (ISL4) may be disposed on the third insulating layer (ISL3). The fourth insulating layer (ISL4) may have a substantially flat top surface. The fourth insulating layer (ISL4) may include an organic insulating material such as polyimide (PI). In an embodiment, a contact hole through which a part of a top surface of the drain electrode (DE) is exposed may be defined in the fourth insulating layer (ISL4). However, the fourth insulating layer (ISL4) according to embodiments of the present invention is not necessarily limited thereto, and a hole through which a part of a top surface of the source electrode (SE) is exposed may be defined in the fourth insulating layer (ISL4).

The pixel defining layer (PDL) may be disposed on the fourth insulating layer (ISL4). The pixel defining layer (PDL) may partially cover the pixel electrode (PE). In addition, a hole through which at least a part of the pixel electrode (PE) is exposed may be defined in the pixel defining layer (PDL). For example, the hole of the pixel defining layer (PDL) may expose a central portion of the pixel electrode (PE), and the pixel defining layer (PDL) may cover an edge of the pixel electrode (PE). The pixel defining layer (PDL) may include the same material as the fourth insulating layer (ISL4).

The pixel electrode (PE) may be disposed on the fourth insulating layer (ISL4). In an embodiment, the pixel electrode (PE) may contact the drain electrode (DE) through the hole. However, the pixel electrode (PE) according to embodiments of the present invention is not necessarily limited thereto, and the pixel electrode (PE) may contact the source electrode (SE) through the hole. The pixel electrode (PE) may include a metal, an alloy, a conductive metal oxide, a conductive metal nitride, a transparent conductive material, or the like. For example, the pixel electrode (PE) may include silver (Ag) and indium tin oxide (ITO).

The light emitting layer (EML) may be disposed on the pixel defining layer (PDL). The light emitting layer (EML) may be disposed on the pixel electrode (PE) exposed by the hole of the pixel defining layer (PDL). The light emitting layer (EML) may include an organic light emitting material. The organic light emitting material may include a low molecular weight organic compound or a high molecular weight organic compound. However, the present invention is not limited thereto, and the light emitting layer (EML) may include a material such as a quantum dot.

The common electrode (CME) may be disposed on the light emitting layer (EML). The common electrode (CME) may include a metal, an alloy, a conductive metal oxide, a conductive metal nitride, a transparent conductive material, or the like. For example, the common electrode (CME) may include aluminum (Al), platinum (Pt), silver (Ag), magnesium (Mg), gold (Au), chromium (Cr), tungsten (W), titanium (Ti), or the like. These may be used alone or in combination. The pixel electrode (PE), the light emitting layer (EML), and the common electrode (CME) may define a light emitting element (EE).

The first encapsulation layer (ENL1) may be disposed on the common electrode (CME). The first encapsulation layer (ENL1) may cover the light emitting element (EE). The first encapsulation layer (ENL1) may have a substantially uniform thickness along a profile of the common electrode (CME). The second encapsulation layer (ENL2) may be disposed on the first encapsulation layer (ENL1). The second encapsulation layer (ENL2) may have a substantially flat top surface without generating a step around the first encapsulation layer (ENL1). The third encapsulation layer (ENL3) may be disposed on the second encapsulation layer (ENL2). The third encapsulation layer (ENL3) may have a substantially uniform thickness and a substantially flat top surface. The first to third encapsulation layers (ENL1, ENL2, and ENL3) may seal the display area (DA) to protect the light emitting element (EE) from external impurities.

The driving circuit part (CC) may be mounted on the display panel (DP). The driving circuit part (CC) may be disposed on a portion overlapping the pad area (PDA) of the display panel (DP).

The multi-functional member (MFE) may be disposed under the display panel (DP). For example, the multi-functional member (MFE) may be disposed under a non-bent portion of the display panel (DP) (for example, a portion overlapping the display area (DA) and the peripheral area (PA) of the display panel (DP)). The multi-functional member (MFE) may perform a role of dissipating heat generated in the display panel (DP) to the outside, supporting the display panel (DP), or blocking light incident from the outside.

The heat dissipation layer (HDL) may include graphite. In an embodiment, the heat dissipation layer (HDL) may include natural graphite or artificial graphite. For example, the heat dissipation layer (HDL) may be pure graphite. A first surface (S1) of the heat dissipation layer (HDL) may face the printed circuit board (PCB). For example, the first surface (S1) of the heat dissipation layer (HDL) may face a direction opposite to the third direction (DR3). A second surface (S2) of the heat dissipation layer (HDL) opposite to the first surface (S1) may face the display panel (DP). For example, the second surface (S2) of the heat dissipation layer (HDL) may face the third direction (DR3).

In the present specification, the first surface (S1) of the heat dissipation layer (HDL) may be designated as one surface of the heat dissipation layer (HDL), and the second surface (S2) of the heat dissipation layer (HDL) may be designated as the other surface of the heat dissipation layer (HDL).

In an embodiment, the thermal conductivity of the heat dissipation layer (HDL) may be about 100 W/(m·K) to about 1700 W/(m·K). Preferably, the thermal conductivity of the heat dissipation layer (HDL) may be about 500 W/(m·K) to about 1700 W/(m·K). The heat dissipation layer (HDL) may efficiently spread the heat generated in the display device (DD) to remove a hot spot of a specific portion of the display device (DD) and lower the overall heat (temperature) of the display device (DD).

In an embodiment, the average thickness of the heat dissipation layer (HDL) may be about 10 μm to about 1000 μm. Preferably, the average thickness of the heat dissipation layer (HDL) may be about 10 μm to about 100 μm.

The cover layer (CVL) may be disposed on the first surface (S1) of the heat dissipation layer (HDL). For example, the cover layer (CVL) may entirely cover the first surface (S1) of the heat dissipation layer (HDL). In an embodiment, the cover layer (CVL) may be a coating layer coated on the first surface (S1) of the heat dissipation layer (HDL). In another embodiment, the cover layer (CVL) may be an adhesive layer adhered on the first surface (S1) of the heat dissipation layer (HDL). In an embodiment, the cover layer (CVL) may cover the first surface (S1) of the heat dissipation layer (HDL) while having a substantially uniform thickness.

In an embodiment, the cover layer (CVL) may include resin. For example, the resin may include acryl, epoxy, polyurethane, silicone, or the like. These may be used alone or in combination.

In another embodiment, the cover layer (CVL) may include resin and filler. For example, the resin may include acryl, epoxy, polyurethane, silicone, or the like, and the filler may include boron nitride (BN), graphite powder, graphene, carbon fiber, carbon nano tube, or the like. These may be used alone or in combination. Specifically, the mass ratio of the resin included in the cover layer (CVL) may be 30 wt % to 90 wt %, and the mass ratio of the filler included in the cover layer (CVL) may be 10 wt % to 70 wt %.

In yet another embodiment, the cover layer (CVL) may include an adhesive material. For example, the cover layer (CVL) may include polyethylene terephthalate (PET). In other words, the cover layer (CVL) may be a single-sided adhesive PET adhered to the first surface (S1) of the heat dissipation layer (HDL).

In an embodiment, the cover layer (CVL) may contact the printed circuit board (PCB). Specifically, when the cover layer (CVL) includes a conductive material, as the cover layer (CVL) contacts the printed circuit board (PCB), the multi-functional member (MFE) may more easily perform roles of electromagnetic interference (EMI) shielding and electrostatic discharge (ESD) shielding.

In an embodiment, the average thickness of the cover layer (CVL) may be about 5 μm to about 50 μm. In an embodiment, the average thickness of the cover layer (CVL) may be smaller than the average thickness of the heat dissipation layer (HDL).

The adhesive layer (ADL) may be disposed on the second surface (S2) of the heat dissipation layer (HDL). The adhesive layer (ADL) may be disposed between the heat dissipation layer (HDL) and the display panel (DP) on a cross section. In an embodiment, the adhesive layer (ADL) may couple the heat dissipation layer (HDL) and the display panel (DP) to each other. For example, the adhesive layer (ADL) may include polyethylene terephthalate. In other words, the adhesive layer (ADL) may be a double-sided adhesive PET that can be adhered to the second surface (S2) of the heat dissipation layer (HDL) and a surface of the display panel (DP) facing the heat dissipation layer (HDL).

In an embodiment, the average thickness of the adhesive layer (ADL) may be about 5μm to about 55 μm. In an embodiment, the average thickness of the adhesive layer (ADL) may be greater than the average thickness of the cover layer (CVL). In an embodiment, the average thickness of the adhesive layer (ADL) may be smaller than the average thickness of the heat dissipation layer (HDL). In an embodiment, a thermal conductivity of the adhesive layer (ADL) may be smaller than the thermal conductivity of the heat dissipation layer (HDL).

The side cover member (SM) may cover the side surface (S3) of the heat dissipation layer (HDL). For example, the side cover member (SM) may entirely surround the side surface (S3) of the heat dissipation layer (HDL). In an embodiment, an edge portion of the cover layer (CVL) may contact the side cover member (SM). For example, the side cover member (SM) may surround the edge portion of the cover layer (CVL). In an embodiment, an edge portion of the adhesive layer (ADL) may contact the side cover member (SM). For example, the side cover member (SM) may surround the edge portion of the adhesive layer (ADL).

In an embodiment, the side cover member (SM) may include acryl, epoxy, polyurethane, boron nitride, graphite powder, graphene, carbon fiber, carbon nano tube, or the like. These may be used alone or in combination. In an embodiment, the side cover member (SM) may include the same material as the cover layer (CVL). In another embodiment, the side cover member (SM) may include a material different from the cover layer (CVL).

In an embodiment, the side cover member (SM) may be coated and formed on the side surface (S3) of the heat dissipation layer (HDL). In another embodiment, the side cover member (SM) may be formed on the side surface (S3) of the heat dissipation layer (HDL) through a process of sealing the side surface (S3) of the heat dissipation layer (HDL).

The printed circuit board (PCB) may be disposed under the cover layer (CVL). As the display panel (DP) is bent in the bending area (BA), the printed circuit board (PCB) may be electrically connected to the display panel (DP). For example, the printed circuit board (PCB) may be electrically connected to the display panel (DP) through the anisotropic conductive film (ACF).

The optical functional layer (OL) may be disposed on the display panel (DP). The optical functional layer (OL) may be a layer that performs an optical function of adjusting light. In an embodiment, the optical functional layer (OL) may be a polarizing layer. The optical functional layer (OL) may be disposed in the display area (DA) and the peripheral area (PA). The optical functional layer (OL) may polarize light incident on the display panel (DP) from the outside. The optical functional layer (OL) may extend in one direction. An extension direction of the optical functional layer (OL) may be an absorption axis, and a direction perpendicular to the extension direction may be a transmission axis. However, the optical functional layer (OL) according to embodiments of the present invention is not necessarily limited to a polarizing layer, and may be various types of functional layers that perform an optical function. For example, the optical functional layer (OL) may include a color filter layer.

The window layer (WN) may be disposed on the optical functional layer (OL). The window layer (WN) may be disposed in the display area (DA), the peripheral area (PA), and the bending area (BA). The window layer (WN) may protect the display panel (DP) and the optical functional layer (OL). The window layer (WN) may include tempered glass, tempered plastic, or the like. The window layer (WN) may be formed as a single layer or may have a structure in which a plurality of functional layers are stacked. The window layer (WN) may prevent occurrence of defects such as fingerprints, scratches, dents, or impacts on the display panel (DP) and the optical functional layer (OL).

As described above, the display device (DD) may include the cover layer (CVL) and the side cover member (SM) for respectively covering the first surface (S1) and the side surface (S3) of the heat dissipation layer (HDL) including graphite. Accordingly, it is possible to prevent a phenomenon in which impurities such as particles flow into the display panel (DP) or the printed circuit board (PCB) from the surface of the heat dissipation layer (HDL).

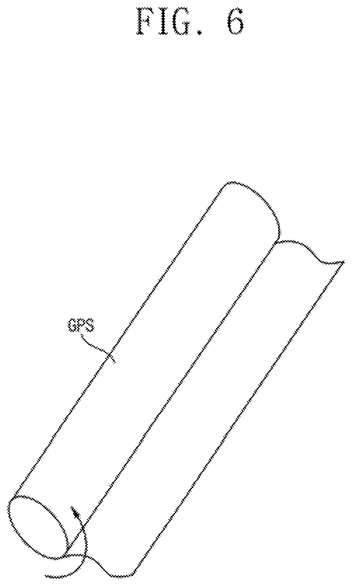

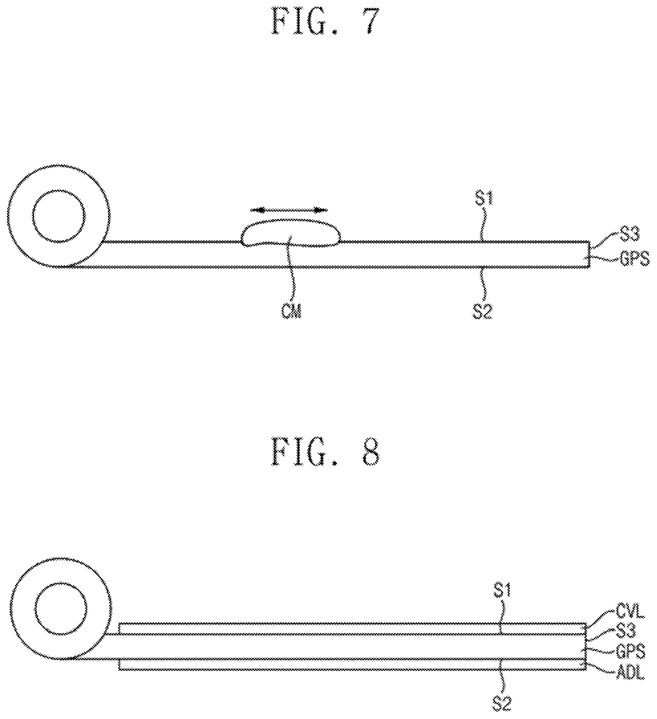

FIGS. 6 to 11 are views for explaining an example of a method of manufacturing the display device of FIG. 1.

Hereinafter, content overlapping with the content described with reference to FIGS. 1 to 5 may be omitted or briefly described.

Referring to FIGS. 6 to 8, after unrolling a graphite sheet (GPS) in a roll state, a cover material (CM) may be formed on a first surface (S1) of an unrolled portion of the graphite sheet (GPS). The cover layer (CVL) may be formed using the cover material (CM) on the first surface (S1) of the unrolled portion of the graphite sheet (GPS). For example, the cover material (CM) may be evenly applied on the first surface (S1) of the graphite sheet (GPS) in a powder or liquid state using a device such as a dispenser. Accordingly, the first surface (S1) of the graphite sheet (GPS) may be coated using the cover material (CM). However, the formation process of the cover material (CM) and the cover layer (CVL) according to embodiments of the present invention is not necessarily limited thereto, and a film-shaped cover layer (CVL) may be manufactured using the cover material (CM), and the film-shaped cover layer (CVL) may be attached on the graphite sheet (GPS).

The cover material (CM) may be a material forming the cover layer (CVL) of FIG. 2. In an embodiment, the cover material (CM) may include resin. For example, the resin may include acryl, epoxy, polyurethane, silicone, or the like. These may be used alone or in combination.

In another embodiment, the cover material (CM) may include resin and filler. For example, the resin may include acryl, epoxy, polyurethane, silicone, or the like, and the filler may include boron nitride, graphite powder, graphene, carbon fiber, carbon nano tube, or the like. These may be used alone or in combination. Specifically, the mass ratio of the resin included in the cover material (CM) may be 30 wt % to 90 wt %, and the mass ratio of the filler included in the cover material (CM) may be 10 wt % to 70 wt %.

In yet another embodiment, the cover material (CM) may include an adhesive material. For example, the cover material (CM) may include polyethylene terephthalate. In other words, the cover material (CM) may be a single-sided adhesive PET adhered to one surface of the graphite sheet (GPS).

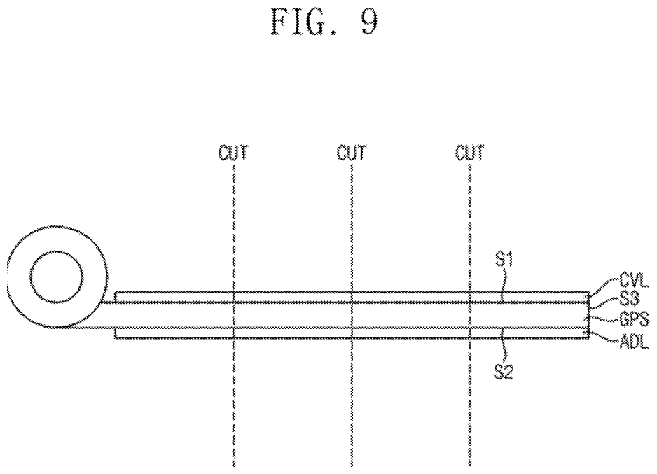

Referring to FIG. 9, the adhesive layer (ADL) may be formed on the second surface (S2) of the unrolled portion of the graphite sheet (GPS). For example, the adhesive layer (ADL) may be adhered to the second surface (S2) of the unrolled portion of the graphite sheet (GPS). After the cover layer (CVL) and the adhesive layer (ADL) are respectively formed on both surfaces of the graphite sheet (GPS), a structure in which the graphite sheet (GPS), the cover layer (CVL), and the adhesive layer (ADL) are combined may be cut to a specific size. For example, the structure may be cut along a cutting line (CUT). Accordingly, the cut structure may be manufactured into a multi-functional member (for example, the multi-functional member (MFE) of FIG. 2). In addition, the graphite sheet (GPS) may be cut to a specific size to form the heat dissipation layer (HDL).

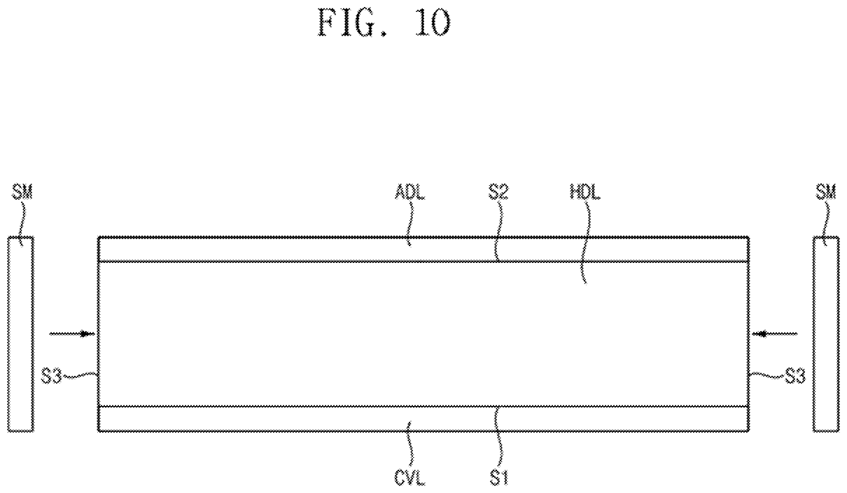

Referring to FIG. 10, a side surface of the manufactured multi-functional member may be exposed. For example, the side surface (S3) of the heat dissipation layer (HDL) may be exposed. The side cover member (SM) may be formed on the exposed side surface (S3) of the heat dissipation layer (HDL). For example, the side surface (S3) of the heat dissipation layer (HDL) may be coated using the side cover member (SM). As another example, the side surface (S3) of the heat dissipation layer (HDL) may be sealed using the side cover member (SM). In an embodiment, the side cover member (SM) may simultaneously cover not only the side surface (S3) of the heat dissipation layer but also the edge portion of the adhesive layer (ADL) and the edge portion of the cover layer (CVL).

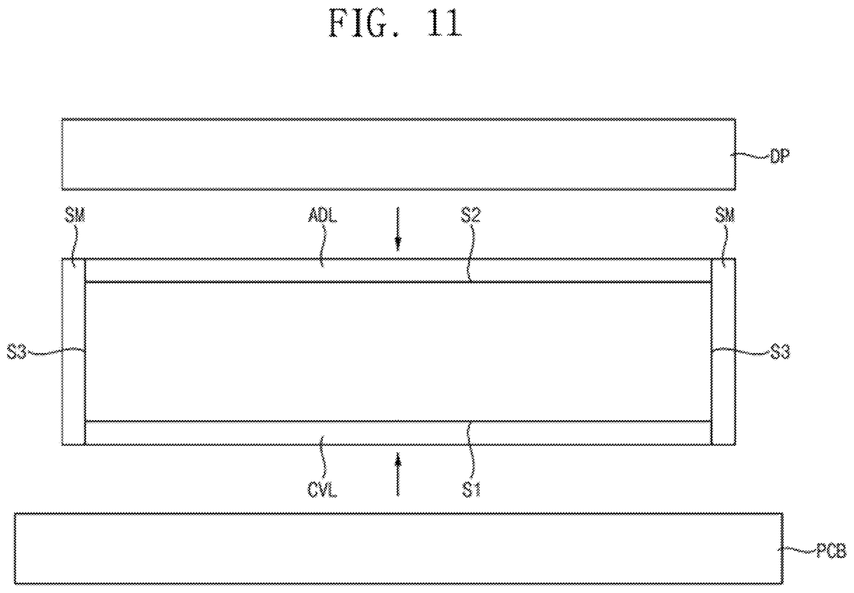

Referring to FIG. 11, the display panel (DP) may be disposed on the multi-functional member, and the printed circuit board (PCB) may be disposed under the multi-functional member. For example, the multi-functional member may be coupled to the display panel (DP) through the adhesive layer (ADL). The multi-functional member may contact the printed circuit board (PCB). Accordingly, the display device (DD) of FIG. 1 may be manufactured.

As described above, in the method of manufacturing the display device (DD), since the cover layer (CVL) covering the heat dissipation layer (HDL) is formed, a lamination process accompanied by heat for protecting the heat dissipation layer (HDL) is not separately required, and accordingly, defects occurring in the display device (DD) may be reduced. Therefore, reliability of the display device (DD) may be improved.

In addition, since the cover layer (CVL) may be formed on the graphite sheet (GPS) while unrolling the graphite sheet (GPS) in a roll state, the manufacturing cost and time of the display device (DD) may be shortened.

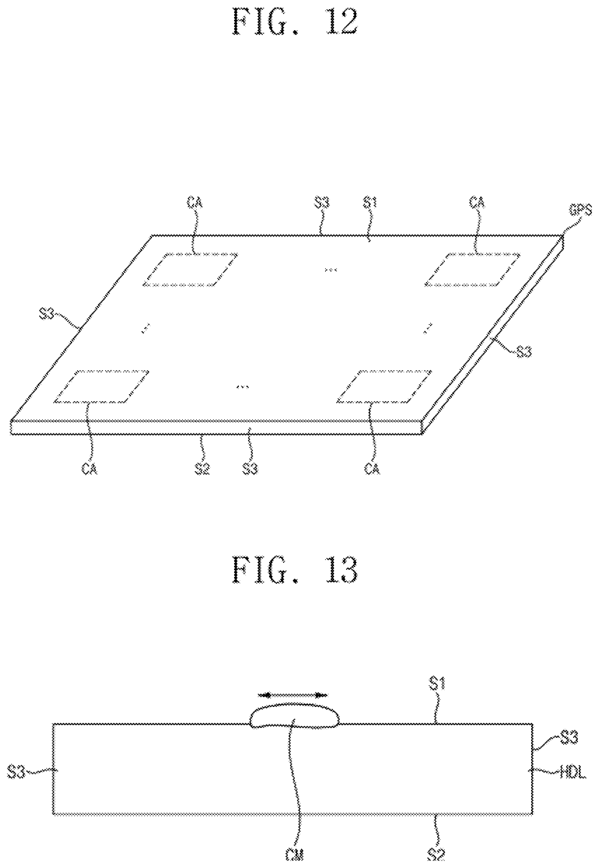

FIGS. 12 and 13 are views for explaining another example of a method of manufacturing the display device of FIG. 1.

The method of manufacturing the display device (DD) described with reference to FIGS. 12 and 13 may be substantially the same as or similar to the method of manufacturing the display device (DD) described with reference to FIGS. 6 to 11, except that the order of the process of cutting the graphite sheet (GPS) and the process of forming the cover layer (CVL) and the adhesive layer (ADL) is different.

Hereinafter, content overlapping with the content described with reference to FIGS. 6 to 11 may be omitted or briefly described.

Referring to FIGS. 2, 12, and 13, after unrolling a graphite sheet (GPS) in a roll state, the heat dissipation layer (HDL) may be formed by cutting the graphite sheet (GPS) along a cutting area (CA). The cutting area (CA) may have a specific size and pattern for manufacturing the heat dissipation layer (HDL) to be used in manufacturing the display device. The cover material (CM) may be formed on the first surface (S1) of the heat dissipation layer (HDL). Thereafter, the cover material (CM) may be entirely applied on the first surface (S1) of the heat dissipation layer (HDL) to form the cover layer (CVL), and the adhesive layer (ADL) may be formed on the second surface (S2) of the heat dissipation layer (HDL). Thereafter, the side cover member (SM) may be formed on the side surface (S3) of the heat dissipation layer (HDL), and accordingly, the multi-functional member (MFE) may be manufactured. The display panel (DP) and the printed circuit board (PCB) may be coupled to the multi-functional member (MFE) to manufacture the display device (DD) of FIG. 1.

In other words, the method of manufacturing the display device described with reference to FIGS. 6 to 11 includes a process in which the cover layer (CVL) is formed on the graphite sheet (GPS) in a roll state and the graphite sheet (GPS) is cut, whereas the method of manufacturing the display device described with reference to FIGS. 12 and 13 may include a process in which the cover layer (CVL) is formed on the heat dissipation layer (HDL) after cutting the graphite sheet (GPS) in a roll state.

As described above, in the method of manufacturing the display device (DD), since the cover layer (CVL) covering the heat dissipation layer (HDL) is formed, a lamination process accompanied by heat for protecting the heat dissipation layer (HDL) is not separately required, and accordingly, defects occurring in the display device (DD) may be reduced. Therefore, reliability of the display device (DD) may be improved.

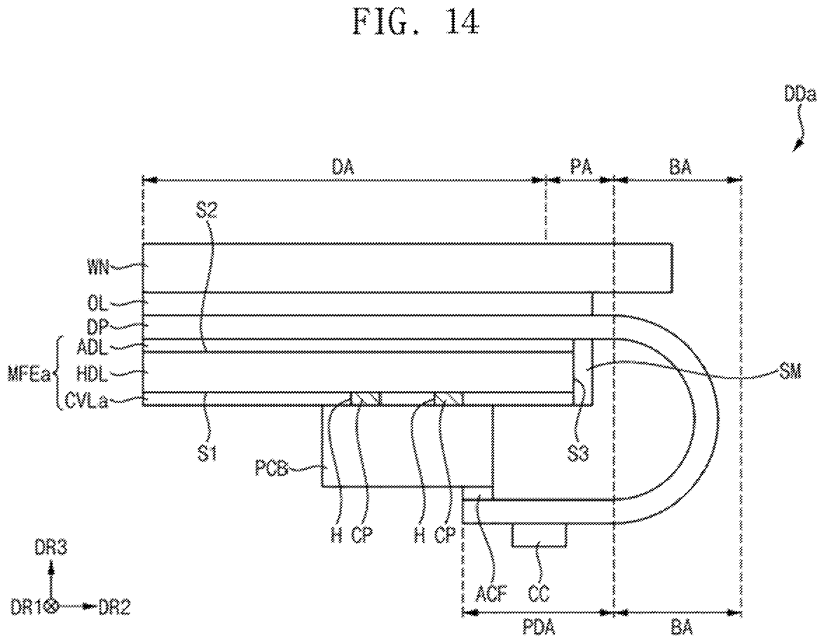

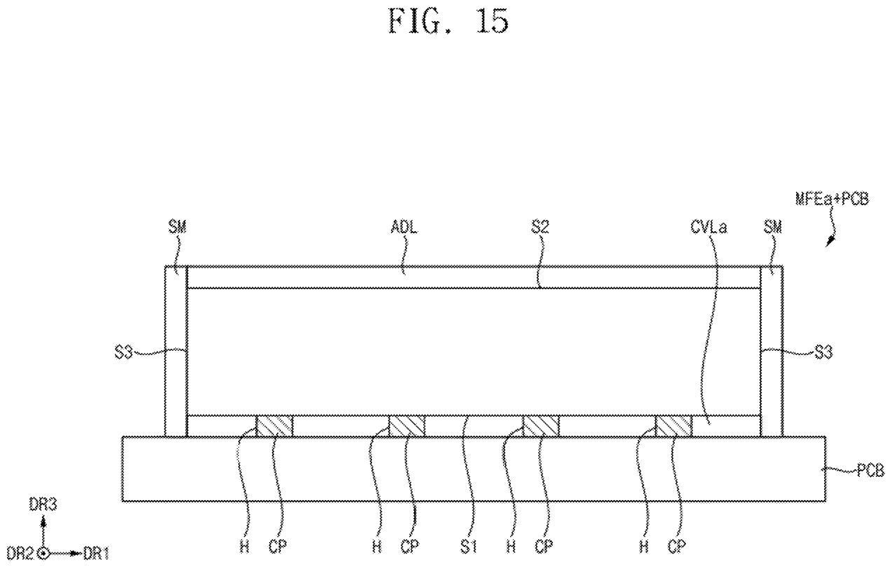

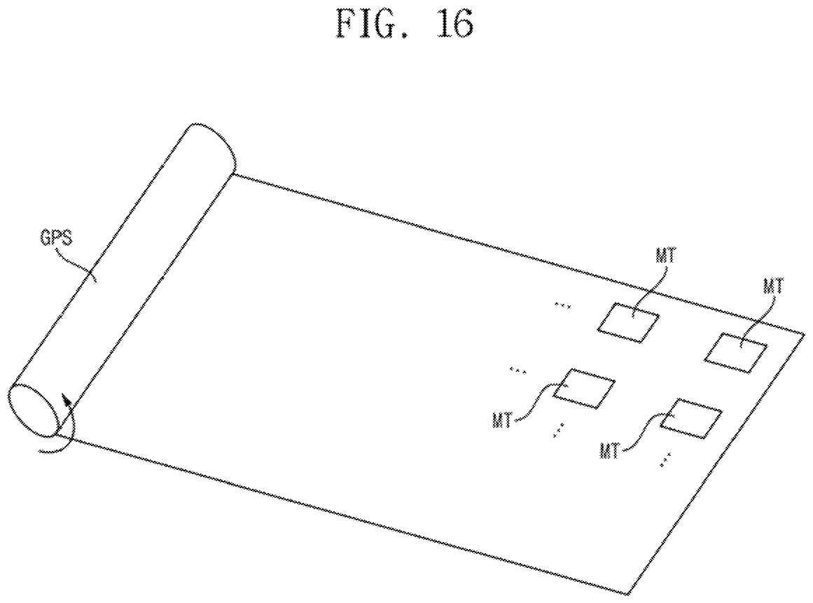

FIG. 14 is a cross-sectional view illustrating a cross section of a display device according to another embodiment of the present invention. FIG. 15 is a cross-sectional view illustrating a cross section of a multi-functional member and a circuit board included in the display device of FIG. 14.

The display device (DDa) described with reference to FIGS. 14 and 15 may be substantially the same as or similar to the display device (DD) described with reference to FIGS. 1 to 5, except for a cover layer (CVLa) and a contact part (CP).

Hereinafter, content overlapping with the content described with reference to FIGS. 1 to 5 may be omitted or briefly described.

Referring to FIGS. 14 and 15, the display device (DDa) may include a multi-functional member (MFEa). The multi-functional member (MFEa) may include the heat dissipation layer (HDL), a cover layer (CVLa) disposed on the first surface (S1) of the heat dissipation layer (HDL), and an adhesive layer (ADL) disposed on the second surface (S2) of the heat dissipation layer (HDL).

At least one contact hole (H) penetrating the cover layer (CVLa) in a thickness direction (for example, the third direction (DR3)) may be defined in the cover layer (CVLa). A plurality of contact holes (H) may be arranged on a plane. For example, a plurality of contact holes (H) may be arranged in the first direction (DR1) and/or the second direction (DR2). However, the number and arrangement of the contact holes (H) according to embodiments of the present invention are not necessarily limited thereto.

The heat dissipation layer (HDL) and the printed circuit board (PCB) may be connected to each other through the contact hole (H). For example, the heat dissipation layer (HDL) and the printed circuit board (PCB) may be electrically or physically connected to each other through a contact part (CP) filling the contact hole (H). The contact part (CP) may contact the first surface (S1) of the heat dissipation layer (HDL) and one surface of the printed circuit board (PCB). In an embodiment, the contact part (CP) may include a material having conductivity.

In an embodiment, the contact part (CP) may be integrally formed with the heat dissipation layer (HDL). For example, the contact part (CP) may be a part of the heat dissipation layer (HDL) protruding from the first surface (S1) of the heat dissipation layer (HDL) toward the printed circuit board (PCB). In another embodiment, the contact part (CP) may be integrally formed with the printed circuit board (PCB). For example, the contact part (CP) may be a part of the printed circuit board (PCB) protruding from the one surface of the printed circuit board (PCB) toward the heat dissipation layer (HDL). In yet another embodiment, the contact part (CP) may be a separate component from each of the heat dissipation layer (HDL) and the printed circuit board (PCB). For example, the contact part (CP) may be a conductive tape such as an anisotropic conductive film, a thermally conductive adhesive, a conductive material, or the like. However, the contact part (CP) according to embodiments of the present invention is not necessarily limited thereto.

In an embodiment, the cover layer (CVLa) may include resin. For example, the resin may include acryl, epoxy, polyurethane, silicone, or the like. These may be used alone or in combination.

In another embodiment, the cover layer (CVLa) may include an adhesive material. For example, the cover layer (CVLa) may include polyethylene terephthalate. In other words, the cover layer (CVLa) may be a single-sided adhesive PET adhered to the first surface (S1) of the heat dissipation layer (HDL).

However, the material included in the cover layer (CVLa) according to embodiments of the present invention is not necessarily limited thereto, and the cover layer (CVLa) may include resin and filler. For example, the resin may include acryl, epoxy, polyurethane, silicone, or the like, and the filler may include boron nitride, graphite powder, graphene, carbon fiber, carbon nano tube, or the like. These may be used alone or in combination.

As described above, the display device (DDa) may include the cover layer (CVLa) and the side cover member (SM) for respectively covering the first surface (S1) and the side surface (S3) of the heat dissipation layer (HDL) including graphite. Accordingly, it is possible to prevent a phenomenon in which impurities such as particles flow into the display panel (DP) or the printed circuit board (PCB) from the surface of the heat dissipation layer (HDL). In addition, the heat dissipation layer (HDL) and the printed circuit board (PCB) may be connected to each other through the contact hole (H). Accordingly, the multi-functional member (MFEa) may more easily perform roles of electromagnetic interference shielding and electrostatic discharge shielding.

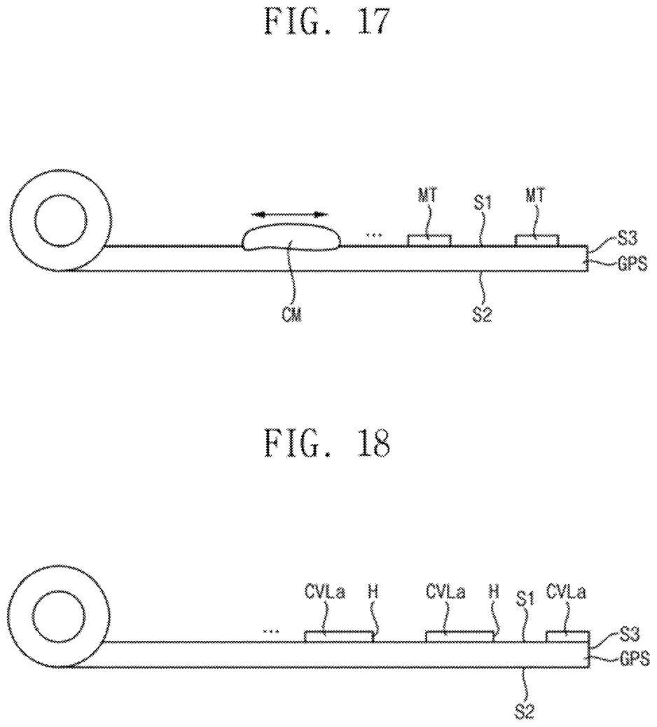

FIGS. 16 to 18 are views for explaining a method of manufacturing the display device of FIG. 14.

The method of manufacturing the display device (DDa) described with reference to FIGS. 16 to 18 may be the same as or similar to the method of manufacturing the display device (DD) described with reference to FIGS. 6 to 11, except for the process in which the contact hole (H) is formed.

Hereinafter, content overlapping with the content described with reference to FIGS. 6 to 11, 14, and 15 may be omitted or briefly described.

Referring to FIGS. 16 to 18, a masking tape (MT) may be attached on the first surface (S1) of the graphite sheet (GPS). The masking tape (MT) may be attached at a specific position on the first surface (S1) of the graphite sheet (GPS). For example, the masking tape (MT) may be attached at a position where the contact hole (H) is formed on the first surface (S1) of the graphite sheet (GPS). After the masking tape (MT) is attached, the cover material (CM) may be formed on the first surface (S1) of the graphite sheet (GPS). After the cover material (CM) is evenly coated on the first surface (S1) of the graphite sheet (GPS), the masking tape (MT) may be removed from the graphite sheet (GPS) to form the cover layer (CVLa) in which the contact hole (H) is defined. After the cover layer (CVLa) is formed, the graphite sheet (GPS) may be cut to manufacture the multi-functional member (MFEa) of FIG. 14, and the multi-functional member (MFEa), the display panel (for example, the display panel (DP) of FIG. 2), and the printed circuit board (for example, the printed circuit board (PCB) of FIG. 2) may be coupled to each other to manufacture the display device (DDa).

However, the process in which the contact hole (H) is formed according to embodiments of the present invention is not necessarily limited thereto, and after entirely covering the first surface (S1) of the graphite sheet (GPS) with the cover material (CM), a part of the cover material (CM) may be removed to form the cover layer (CVLa) in which the contact hole (H) is defined.

As described above, in the method of manufacturing the display device (DDa), since the cover layer (CVLa) covering the heat dissipation layer (HDL) is formed, a lamination process accompanied by heat for protecting the heat dissipation layer (HDL) is not separately required, and accordingly, defects occurring in the display device (DDa) may be reduced. Therefore, reliability of the display device (DDa) may be improved.

In addition, since the contact hole (H) is formed using the masking tape (MT), the manufacturing process and time of the multi-functional member (MFEa) performing roles of electromagnetic interference shielding and electrostatic discharge shielding may be shortened.

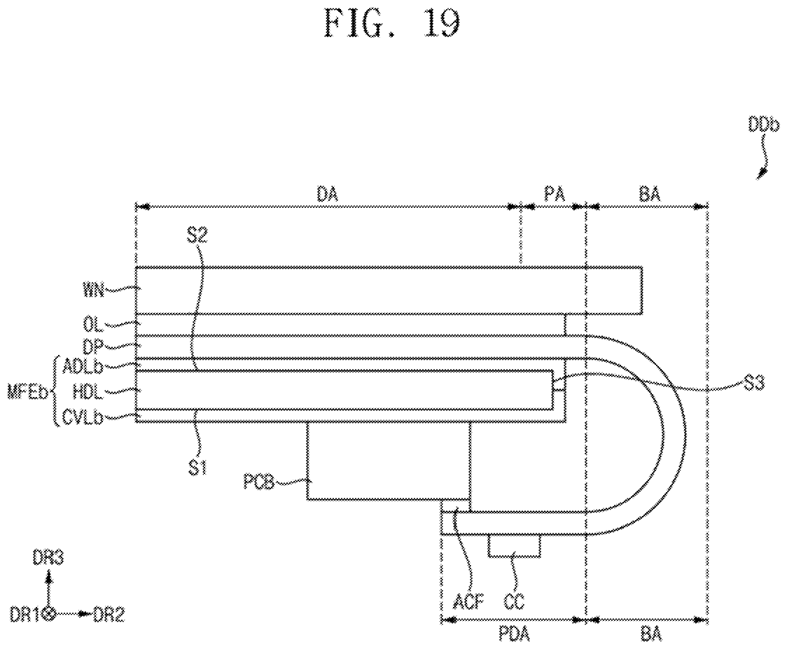

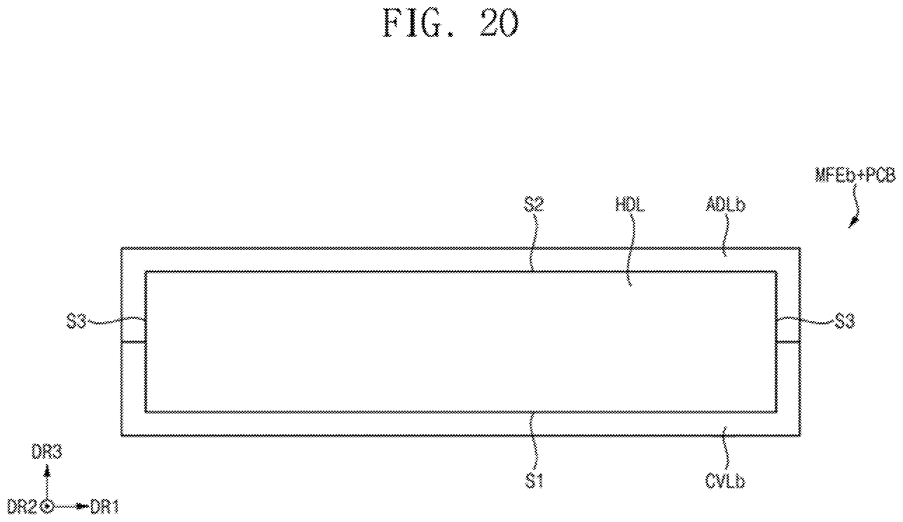

FIG. 19 is a cross-sectional view illustrating a cross section of a display device according to yet another embodiment of the present invention. FIG. 20 is a cross-sectional view illustrating a cross section of a multi-functional member included in the display device of FIG. 19.

The display device (DDb) described with reference to FIGS. 19 and 20 may be the same as or similar to the display device (DD) described with reference to FIGS. 1 to 5, except for a cover layer (CVLb) and an adhesive layer (ADLb).

Hereinafter, content overlapping with the content described with reference to FIGS. 1 to 5 may be omitted or briefly described.

Referring to FIGS. 19 and 20, the display device (DDb) may include a multi-functional member (MFEb). The multi-functional member (MFEb) may include the heat dissipation layer (HDL), a cover layer (CVLb) disposed on the first surface (S1) of the heat dissipation layer (HDL), and an adhesive layer (ADLb) disposed on the second surface (S2) of the heat dissipation layer (HDL). In the present specification, the cover layer (CVLb) may be designated as a first cover layer, and the adhesive layer (ADLb) may be designated as a second cover layer.

In an embodiment, the cover layer (CVLb) may cover the first surface (S1) and a part of the side surface (S3) of the heat dissipation layer (HDL). For example, the cover layer (CVLb) may extend from the first surface (S1) of the heat dissipation layer (HDL) to cover a part of the side surface (S3) of the heat dissipation layer (HDL). In an embodiment, the cover layer (CVLb) may be adhered to the first surface (S1) of the heat dissipation layer (HDL). In an embodiment, the cover layer (CVLb) may include polyethylene terephthalate. In other words, the cover layer (CVLb) may be a single-sided adhesive PET. However, the material included in the cover layer (CVLb) according to embodiments of the present invention is not necessarily limited thereto, and the cover layer (CVLb) may include resin and/or filler.

In an embodiment, the adhesive layer (ADLb) may cover the second surface (S2) and a part of the side surface (S3) of the heat dissipation layer (HDL). For example, the adhesive layer (ADLb) may extend from the second surface (S2) of the heat dissipation layer (HDL) to cover a part of the side surface (S3) of the heat dissipation layer (HDL). In an embodiment, the adhesive layer (ADLb) may couple the heat dissipation layer (HDL) and the display panel (DP) to each other on the second surface (S2) of the heat dissipation layer (HDL). In other words, the adhesive layer (ADLb) may be a double-sided adhesive PET.

In an embodiment, the cover layer (CVLb) and the adhesive layer (ADLb) may entirely cover the side surface (S3) of the heat dissipation layer (HDL). For example, the cover layer (CVLb) and the adhesive layer (ADLb) may contact each other on the side surface (S3) of the heat dissipation layer (HDL), and the cover layer (CVLb) may entirely surround the side surface (S3) of the heat dissipation layer (HDL) together with the adhesive layer (ADLb).

As described above, the display device (DDb) may include the cover layer (CVLb) and the adhesive layer (ADLb) for respectively covering the first surface (S1), the second surface (S2), and the side surface (S3) of the heat dissipation layer (HDL) including graphite. Accordingly, it is possible to prevent a phenomenon in which impurities such as particles flow into the display panel (DP) or the printed circuit board (PCB) from the surface of the heat dissipation layer (HDL).

In addition, unlike the display device (DD) of FIG. 1, the display device (DDb) of FIG. 19 may not include a side cover member (for example, the side cover member (SM) of FIG. 2). For example, since the cover layer (CVLb) and the adhesive layer (ADLb) entirely surround the side surface (S3) of the heat dissipation layer (HDL) in the display device (DDb) of FIG. 19, the cover layer (CVLb) and the adhesive layer (ADLb) may perform the role of the side cover member.

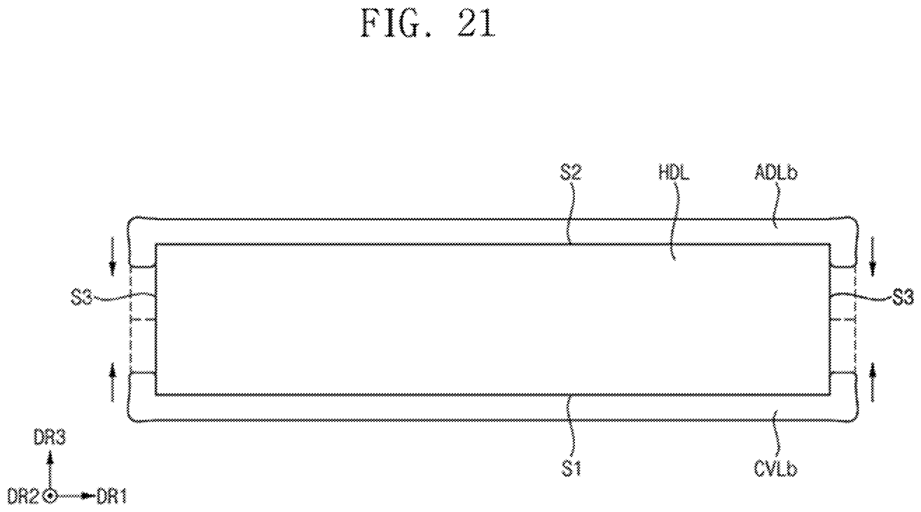

FIG. 21 is a view for explaining a method of manufacturing the display device of FIG. 19.

The method of manufacturing the display device (DDb) described with reference to FIG. 21 may be the same as or similar to the method of manufacturing the display device (DD) described with reference to FIGS. 6 to 11, except for the process of covering the side surface (S3) of the heat dissipation layer (HDL) using the cover layer (CVLb) and the adhesive layer (ADLb).

Hereinafter, content overlapping with the content described with reference to FIGS. 6 to 11, 19, and 20 may be omitted or briefly described.

Referring to FIG. 21, a material forming the cover layer (CVLb) may be entirely applied on the first surface (S1) of the heat dissipation layer (HDL). A material forming the adhesive layer (ADLb) may be entirely applied on the second surface (S2) of the heat dissipation layer (HDL). Pressure or heat may be applied to the material forming the cover layer (CVLb) so that the material forming the cover layer (CVLb) covers a part of the side surface (S3) of the heat dissipation layer (HDL). The pressure or the heat may be applied to the material forming the adhesive layer (ADLb) so that the material forming the adhesive layer (ADLb) covers a part of the side surface (S3) of the heat dissipation layer (HDL). The pressure or the heat may be applied until the material forming the adhesive layer (ADLb) and the material forming the cover layer (CVLb) contact each other on the side surface (S3) of the heat dissipation layer (HDL). Accordingly, the cover layer (CVLb) covering the first surface (S1) and a part of the side surface (S3) of the heat dissipation layer (HDL), and the adhesive layer (ADLb) covering the second surface (S2) and a part of the side surface (S3) of the heat dissipation layer (HDL) may be formed. Accordingly, the multi-functional member (MFEb) of FIG. 19 may be manufactured, and the multi-functional member (MFEb), the display panel (for example, the display panel (DP) of FIG. 2), and the printed circuit board (for example, the printed circuit board (PCB) of FIG. 2) may be coupled to each other to manufacture the display device (DDb).

As described above, in the method of manufacturing the display device (DDb), since the cover layer (CVLb) for covering the heat dissipation layer (HDL) is formed, a lamination process accompanied by heat for protecting the heat dissipation layer (HDL) is not separately required, and accordingly, defects occurring in the display device (DDb) may be reduced. Accordingly, reliability of the display device (DDb) may be improved.

In addition, since the cover layer (CVLb) and the adhesive layer (ADLb) covering the side surface (S3) of the heat dissipation layer (HDL) are formed by applying heat or pressure to the materials forming the cover layer (CVLb) and the adhesive layer (ADLb), respectively, the time and cost for manufacturing the display device (DDb) may be shortened.

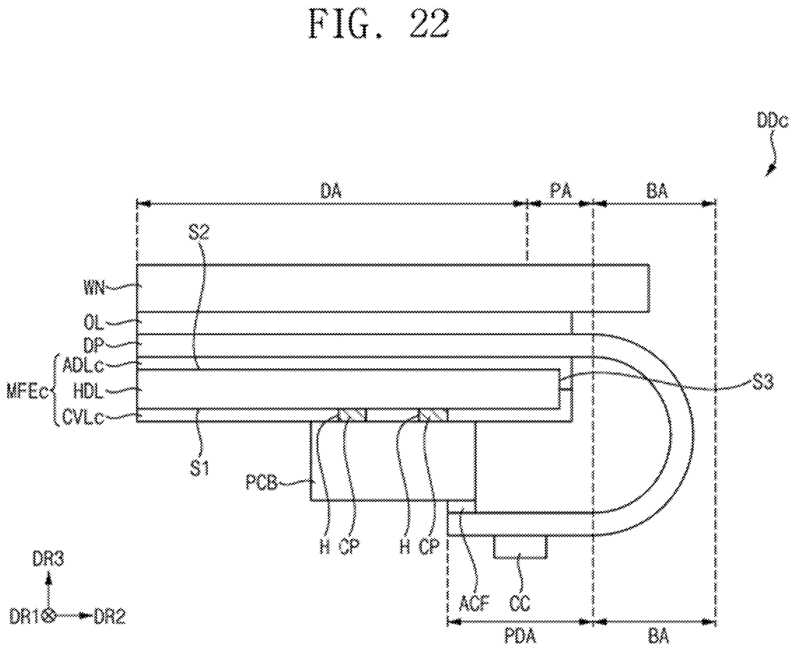

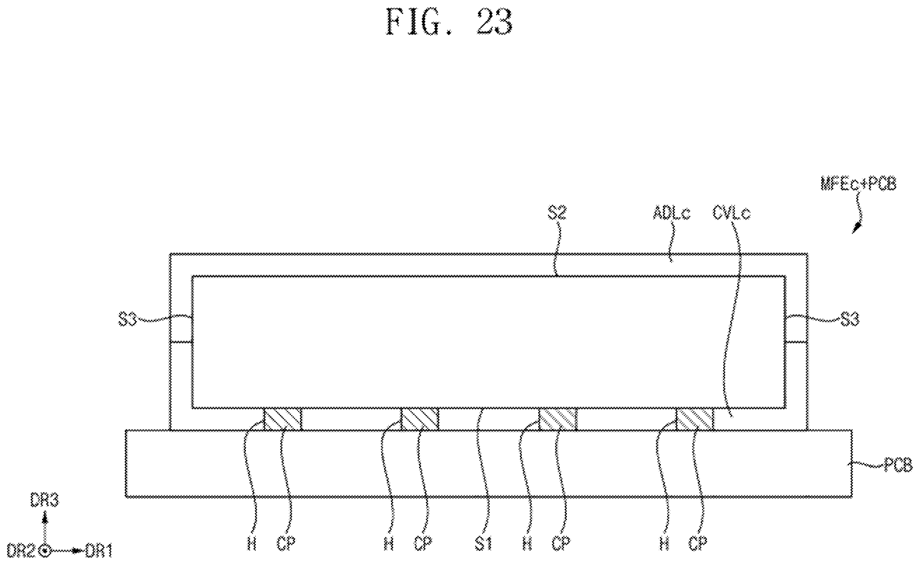

FIG. 22 is a cross-sectional view illustrating a cross section of a display device according to yet another embodiment of the present invention. FIG. 23 is a cross-sectional view illustrating a cross section of a multi-functional member and a circuit board included in the display device of FIG. 22.

The display device (DDc) described with reference to FIGS. 22 and 23 may be substantially the same as or similar to the display device (DDb) described with reference to FIGS. 19 and 20, except for a cover layer (CVLc) and a contact part (CP).

Hereinafter, content overlapping with the content described with reference to FIGS. 19 and 20 may be omitted or briefly described.

Referring to FIGS. 22 and 23, the display device (DDc) may include a multi-functional member (MFEc). The multi-functional member (MFEc) may include the heat dissipation layer (HDL), a cover layer (CVLc) disposed on the first surface (S1) of the heat dissipation layer (HDL), and an adhesive layer (ADLc) disposed on the second surface (S2) of the heat dissipation layer (HDL).

At least one contact hole (H) penetrating the cover layer (CVLc) in a thickness direction (for example, the third direction (DR3)) may be defined in the cover layer (CVLc). A plurality of contact holes (H) may be arranged on a plane. For example, a plurality of contact holes (H) may be arranged in the first direction (DR1) and/or the second direction (DR2). However, the number and arrangement of the contact holes (H) according to embodiments of the present invention are not necessarily limited thereto.

The heat dissipation layer (HDL) and the printed circuit board (PCB) may be connected to each other through the contact hole (H). For example, the heat dissipation layer (HDL) and the printed circuit board (PCB) may be electrically or physically connected to each other through a contact part (CP) filling the contact hole (H). The contact part (CP) may contact the first surface (S1) of the heat dissipation layer (HDL) and one surface of the printed circuit board (PCB). In an embodiment, the contact part (CP) may include a material having conductivity.

In an embodiment, the contact part (CP) may be integrally formed with the heat dissipation layer (HDL). For example, the contact part (CP) may be a part of the heat dissipation layer (HDL) protruding from the first surface (S1) of the heat dissipation layer (HDL) toward the printed circuit board (PCB). In another embodiment, the contact part (CP) may be integrally formed with the printed circuit board (PCB). For example, the contact part (CP) may be a part of the printed circuit board (PCB) protruding from the one surface of the printed circuit board (PCB) toward the heat dissipation layer (HDL). In yet another embodiment, the contact part (CP) may be a separate component from each of the heat dissipation layer (HDL) and the printed circuit board (PCB). For example, the contact part (CP) may be a conductive tape such as an anisotropic conductive film, a thermally conductive adhesive, a conductive material, or the like. However, the contact part (CP) according to embodiments of the present invention is not necessarily limited thereto.

As described above, the display device (DDc) may include the cover layer (CVLc) and the adhesive layer (ADLc) for respectively covering the first surface (S1), the second surface (S2), and the side surface (S3) of the heat dissipation layer (HDL) including graphite. Accordingly, it is possible to prevent a phenomenon in which impurities such as particles flow into the display panel (DP) or the printed circuit board (PCB) from the surface of the heat dissipation layer (HDL).

In addition, the heat dissipation layer (HDL) and the printed circuit board (PCB) may be connected to each other through the contact hole (H). Accordingly, the multi-functional member (MFEc) may more easily perform roles of electromagnetic interference shielding and electrostatic discharge shielding.

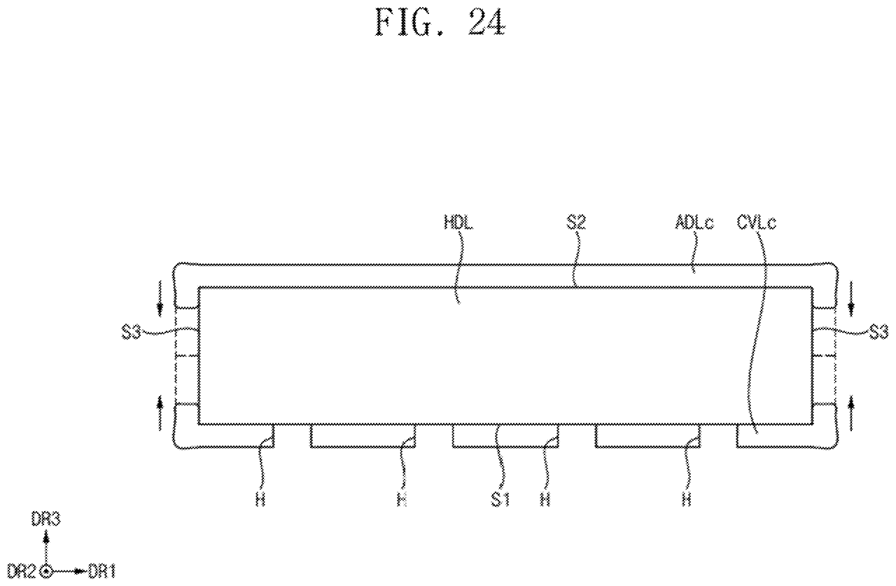

FIG. 24 is a view for explaining a method of manufacturing the display device of FIG. 22.

The method of manufacturing the display device (DDc) described with reference to FIG. 24 may be the same as or similar to the method of manufacturing the display device (DD) described with reference to FIGS. 6 to 11, except for the process of covering the side surface (S3) of the heat dissipation layer (HDL) using the cover layer (CVLc) and the adhesive layer (ADLc) and the process in which the contact hole (H) is formed. In addition, the method of manufacturing the display device (DDc) described with reference to FIG. 24 may be the same as or similar to the method of manufacturing the display device (DDb) described with reference to FIG. 21, except for the process in which the contact hole (H) is formed.

Hereinafter, content overlapping with the content described with reference to FIGS. 6 to 11 and 21 to 23 may be omitted or briefly described.

Referring to FIG. 24, by applying heat or pressure to each of a material forming the cover layer (CVLc) and a material forming the adhesive layer (ADLc), the cover layer (CVLc) and the adhesive layer (ADLc) covering the side surface (S3) of the heat dissipation layer (HDL) may be formed. In addition, a part of the cover layer (CVLc) may be removed to form the contact hole (H). The contact hole (H) may be formed using a masking tape (for example, the masking tape (MT) of FIG. 16). However, the formation process of the contact hole (H) according to embodiments of the present invention is not necessarily limited thereto.

In an embodiment, the process of applying the heat or pressure may be performed before the process in which the contact hole (H) is formed. In another embodiment, the process of applying the heat or pressure may be performed after the process in which the contact hole (H) is formed. In yet another embodiment, the process of applying the heat or pressure may be performed simultaneously with the process in which the contact hole (H) is formed.

As described above, in the method of manufacturing the display device (DDc), since the cover layer (CVLc) covering the heat dissipation layer (HDL) is formed, a lamination process accompanied by heat for protecting the heat dissipation layer (HDL) is not separately required, and accordingly, defects occurring in the display device (DDc) may be reduced. Accordingly, reliability of the display device (DDc) may be improved.

In addition, since the contact hole (H) is formed using the masking tape, the manufacturing process and time of the multi-functional member (MFEc) performing roles of electromagnetic interference shielding and electrostatic discharge shielding may be shortened.

In addition, since the cover layer (CVLc) and the adhesive layer (ADLc) covering the side surface (S3) of the heat dissipation layer (HDL) are formed by applying heat or pressure to the materials forming the cover layer (CVLc) and the adhesive layer (ADLc), respectively, the time and cost for manufacturing the display device (DDc) may be shortened.

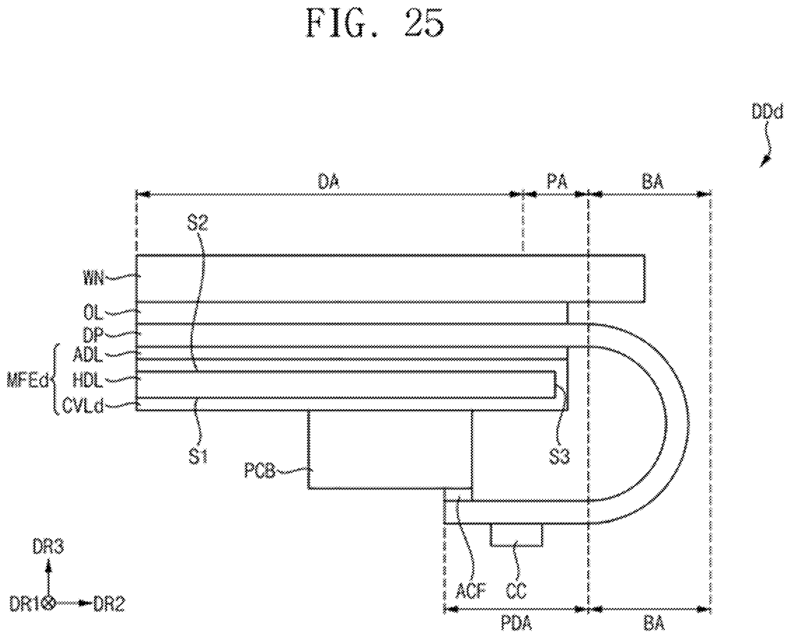

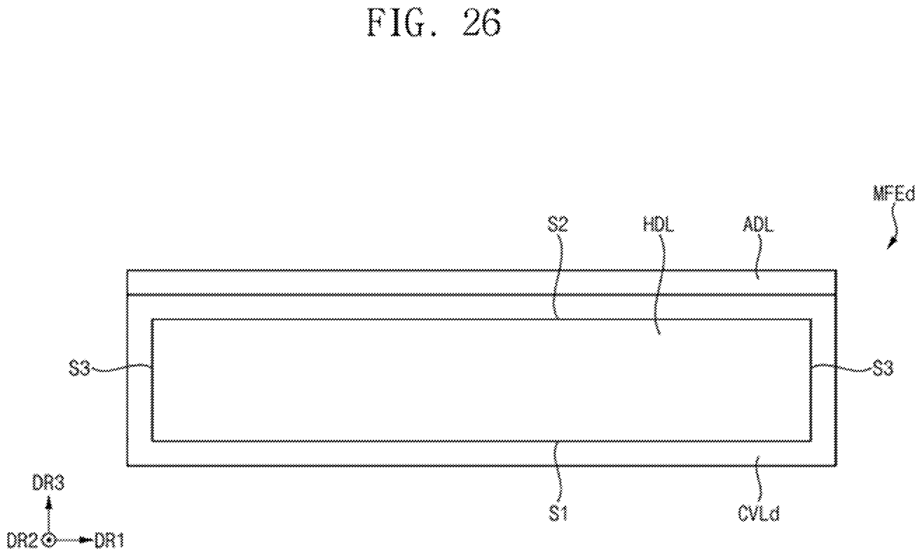

FIG. 25 is a cross-sectional view illustrating a cross section of a display device according to yet another embodiment of the present invention. FIG. 26 is a cross-sectional view illustrating a cross section of a multi-functional member included in the display device of FIG. 25.

The display device (DDd) described with reference to FIGS. 25 and 26 may be substantially the same as or similar to the display device (DD) described with reference to FIGS. 1 to 5, except for a cover layer (CVLd).

Hereinafter, content overlapping with the content described with reference to FIGS. 1 to 5 may be omitted or briefly described.

Referring to FIGS. 25 and 26, the multi-functional member (MFEd) may include the heat dissipation layer (HDL), a cover layer (CVLd) covering the heat dissipation layer (HDL), and an adhesive layer (ADL) disposed on the cover layer (CVLd). In an embodiment, the cover layer (CVLd) may include a metal material having conductivity. For example, the metal material may include aluminum (Al), copper (Cu), silver (Ag), or the like. These may be used alone or in combination with each other. In an embodiment, the cover layer (CVLd) may be a metal coating layer. For example, the cover layer (CVLd) may be formed through a plating process. In an embodiment, an average thickness of the cover layer (CVLd) may be about 1 μm to about 20 μm.

In an embodiment, the cover layer (CVLd) may surround all of the first surface (S1), the second surface (S2), and the side surface (S3) of the heat dissipation layer (HDL). In an embodiment, the cover layer (CVLd) may contact the printed circuit board (PCB). The adhesive layer (ADL) may be adhered on one surface of the cover layer (CVLd). The adhesive layer (ADL) may couple the multi-functional member (MFEd) and the display panel (DP).

As described above, the display device (DDd) may include the cover layer (CVLd) for covering the first surface (S1), the second surface (S2), and the side surface (S3) of the heat dissipation layer (HDL) including graphite. Accordingly, it is possible to prevent a phenomenon in which impurities such as particles flow into the display panel (DP) or the printed circuit board (PCB) from the surface of the heat dissipation layer (HDL).

As described above, in the method of manufacturing the display device (DDd), since the cover layer (CVLd) is formed by plating the heat dissipation layer (HDL), a lamination process accompanied by heat for protecting the heat dissipation layer (HDL) is not separately required, so that defects occurring in the display device (DDd) may be reduced. Accordingly, reliability of the display device (DDd) may be improved.

### INDUSTRIAL APPLICABILITY

The present invention may be applied to a display device and an electronic device including the same. For example, the present invention may be applied to a high-resolution smartphone, a mobile phone, a smart pad, a smart watch, a tablet PC, a vehicle navigation system, a television, a computer monitor, a notebook computer, or the like.

Although the exemplary embodiments of the present invention have been described above, those of ordinary skill in the art will understand that the present invention may be variously modified and changed within the scope not departing from the spirit and scope of the present invention described in the claims below.

What is claimed is:

1. A display device comprising:
a display panel including at least one pixel;
a printed circuit board disposed under the display panel and electrically connected to the pixel;
a heat dissipation layer including graphite and disposed between the display panel and the printed circuit board;
a cover layer disposed on one surface of the heat dissipation layer facing the printed circuit board; and
a side cover member including resin and covering a side surface of the heat dissipation layer.

2. The display device of claim 1, wherein the cover layer includes a material identical to a material of the side cover member.

3. The display device of claim 1, wherein the cover layer includes a material different from a material of the side cover member.

4. The display device of claim 1, wherein the cover layer includes at least one material selected from a resin group consisting of acryl, epoxy, polyurethane, and silicone.

5. The display device of claim 4, wherein the cover layer further includes at least one material selected from a filler group consisting of boron nitride (BN), graphite powder, graphene, carbon fiber, and carbon nano tube,
a mass ratio of the resin group included in the cover layer is 30 wt % to 90 wt %, and
a mass ratio of the filler group included in the cover layer is 10 wt % to 70 wt %.

6. The display device of claim 1, wherein an average thickness of the heat dissipation layer is greater than an average thickness of the cover layer,
the average thickness of the heat dissipation layer is 10 μm to 1000 μm, and
the average thickness of the cover layer is 5 μm to 50 μm.

7. The display device of claim 1, wherein a thermal conductivity of the heat dissipation layer is 100 W/(m·K) to 1700 W/(m·K).

8. The display device of claim 1, wherein the cover layer is adhered to the one surface of the heat dissipation layer and includes polyethylene terephthalate (PET).

9. The display device of claim 1, wherein a contact hole penetrating the cover layer in a thickness direction is defined in the cover layer, and
the heat dissipation layer is connected to the printed circuit board through the contact hole.

10. The display device of claim 1, further comprising:
an adhesive layer disposed between the display panel and the heat dissipation layer,
wherein an average thickness of the adhesive layer is greater than an average thickness of the cover layer and smaller than an average thickness of the heat dissipation layer, and
the adhesive layer couples the heat dissipation layer and the display panel to each other and includes polyethylene terephthalate.

11. A display device comprising:
a display panel including at least one pixel;
a printed circuit board disposed under the display panel and electrically connected to the pixel;
a heat dissipation layer including graphite and disposed between the display panel and the printed circuit board;
a first cover layer disposed on one surface of the heat dissipation layer facing the printed circuit board, and extending from the one surface to cover a part of a side surface of the heat dissipation layer; and
a second cover layer disposed on the other surface of the heat dissipation layer opposite to the one surface, and extending from the other surface to contact the first cover layer.

12. The display device of claim 11, wherein the first cover layer is adhered to the one surface of the heat dissipation layer and includes polyethylene terephthalate, and
the second cover layer couples the heat dissipation layer and the display panel to each other on the other surface of the heat dissipation layer and includes polyethylene terephthalate.

13. The display device of claim 12, wherein a contact hole penetrating the first cover layer in a thickness direction is defined in the first cover layer, and
the heat dissipation layer is connected to the printed circuit board through the contact hole.

14. The display device of claim 11, wherein the first cover layer and the second cover layer are integrally formed to define a single metal coating layer surrounding all of the one surface, the other surface, and the side surface of the heat dissipation layer, and
an average thickness of the metal coating layer is 1 μm to 20 μm.

15. A method of manufacturing a display device, the method comprising:
forming a cover layer on one surface of a heat dissipation layer including graphite;
forming an adhesive layer on the other surface of the heat dissipation layer opposite to the one surface; and
covering a side surface of the heat dissipation layer using a polymer material or a metal material.

16. The method of manufacturing a display device of claim 15, wherein the forming of the cover layer on the one surface of the heat dissipation layer comprises:
unrolling a graphite sheet in a roll state;
coating a material forming the cover layer on one surface of the graphite sheet; and
cutting the graphite sheet and the coated cover layer, and
wherein, in the covering of the side surface of the heat dissipation layer, the side surface of the heat dissipation layer is surrounded by a side cover member.

17. The method of manufacturing a display device of claim 15, wherein the forming of the cover layer on the one surface of the heat dissipation layer comprises:
unrolling a graphite sheet in a roll state;
forming the heat dissipation layer by cutting the graphite sheet; and
coating a material forming the cover layer on the one surface of the heat dissipation layer, and
wherein, in the covering of the side surface of the heat dissipation layer, the side surface of the heat dissipation layer is surrounded by a side cover member.

18. The method of manufacturing a display device of claim 15, wherein the covering of the side surface of the heat dissipation layer comprises:
stretching the cover layer from the one surface of the heat dissipation layer to the side surface;
forming the adhesive layer from the other surface of the heat dissipation layer to the side surface; and
bringing the cover layer and the adhesive layer into contact with each other so that the cover layer and the adhesive layer seal the side surface of the heat dissipation layer.

19. The method of manufacturing a display device of claim 15, wherein the forming of the cover layer on the one surface of the heat dissipation layer comprises:
unrolling a graphite sheet in a roll state;
forming the heat dissipation layer by cutting the graphite sheet; and
plating the heat dissipation layer so that the cover layer surrounds all of the one surface, the other surface, and the side surface of the heat dissipation layer, and
wherein, in the forming of the adhesive layer on the other surface of the heat dissipation layer opposite to the one surface, the adhesive layer contacts the cover layer surrounding the heat dissipation layer.

20. The method of manufacturing a display device of claim 15, further comprising:
forming a contact hole penetrating the cover layer in a thickness direction; and
electrically connecting the cover layer and a printed circuit board through the contact hole,
wherein the cover layer includes at least one material selected from a resin group consisting of acryl, epoxy, polyurethane, polyethylene terephthalate, and silicone.
